(19) United States
(12) Patent Application Publication
(10) Pub. No.: US 2009/0267183 A1
(43) Pub. Date: Oct. 29, 2009

(54) Through-substrate power-conducting via with embedded capacitance

(75) Inventors: Dorota Temple, Cary, NC (US); Robert O. Conn, Hawaii, HI (US)

Correspondence Address: Imperium Patent Works, P.O. Box 587, Sunol, CA, 94586, US

(73) Assignee: Research Triangle Institute

(21) Appl. No.: 12/150,529

(22) Filed: Apr. 28, 2008

(51) Int. Cl. H01L 29/92; H01L 21/02

(52) U.S. Cl. 257/532; 438/386; 257/E29.343; 257/E21.008

(57) ABSTRACT

When integrated circuits are mounted on a substrate, little space is often available for the required large number of bypass capacitors. A novel substrate structure therefore includes many closely spaced through-holes that extend from a first surface of the substrate to a second surface of the substrate. Each through-hole includes a first conducting layer, a dielectric layer, and a second conducting layer. The first and second conducting layers and the intervening dielectric layer constitute a via having a substantial capacitance (one picofarad). Some of the many vias provide bypass capacitance directly under the integrated circuits. A first set of vias supplies power from a power bus bar on one side of the substrate to the integrated circuits on the other side. A second set of vias sinks current from the integrated circuits on the other side, through the substrate, and to a ground bus bar on the one side.

### TECHNICAL FIELD

The described embodiments relate to a substrate involving many through-substrate, power-conducting, capacitive vias.

### BACKGROUND INFORMATION

Large high-speed integrated circuits (ICs) often require decoupling capacitors (also known as bypass capacitors). A typical decoupling capacitor is a capacitor coupled between the power and ground terminals (for example, pins) of a packaged IC to reduce noise on the power system within the IC. While in some cases the IC itself includes some decoupling capacitance, the amount of capacitance required is so large that one or more additional discrete decoupling capacitors are usually added external to the packaged IC. When a typical large state-of-the-art Field Programmable Gate Array (FPGA) is mounted on a printed circuit board (PCB) or other suitable substrate, some sixty bypass capacitors may be required. With space on the PCB or substrate being limited, it can be difficult to find the room needed for all the discrete bypass capacitors.

In the past, the location of discrete decoupling capacitors was a less important issue. The switching frequency of digital integrated circuits was relatively low, e.g., in the range of hundreds of kHz (kilohertz) to tens of MHz (megahertz). Transient currents within the devices were also relatively low. Hence, parasitic inductance in the PCB mountings was not an important consideration. For example, for an IC mounted in a medium-performance package, a 0.1 uF (microfarad) decoupling capacitor could typically be mounted on the PCB anywhere within a few inches of the packaged IC.

Many digital ICs are now clocked at frequencies in the hundreds of megahertz. At these higher frequencies, transient currents are significantly higher than in the past, and parasitic inductance is a much more important issue. It is therefore desirable to provide systems and structures that provide decoupling capacitance to IC devices with reduced parasitic inductance between the bypass capacitance and the IC. It is further desirable to reduce the space consumed by the bypass capacitance.

Large state-of-the-art integrated circuits “IC's” may contain several million active components. One type of device fitting this description is the large FPGA. FPGAs and other devices may operate at speeds of several hundred megahertz and it is not unusual that these integrated circuits include over a thousand terminals that bring high-speed signals into and out of the integrated circuit die. With a large number of active internal components switching at high speeds, these devices consume large amounts of power. A packaging solution is therefore desired that allows for the distribution of hundreds of high-speed signal lines and also provides for thousands of connections to supply power to the device. To solve this problem for a single FPGA, IC designers have used a technique wherein thousands of “bumps” are distributed over the surface of a flip-chip mounted FPGA. It would not be unusual to have two thousand bumps for power and another two thousand for ground. The large number of bumps reserved for power ensures only a minimal resistive drop from the surface of the device to the active devices within the FPGA.

In one example, the power and signal connections extend from the bumps present on the surface of the FPGA to balls of a ball-grid-array “BGA” package that contains the FPDA die. A BGA package utilized for packaging such a large FPGA may have approximately fifteen hundred balls; one thousand for input and output “I/O” connections and five hundred for power and ground connections. Power is supplied from the balls of the BGA package, through thick metal conductors within the package, and to the bumps present on the surface of the FPGA.

The bumped FPGA construction and BGA package is adequate to power and to connect a single FPGA to a substrate, but it is not generally adequate to power and connect a system of many FPGAs. The problems associated with the large number of signals and the high power requirements of a single FPGA are multiplied when several FPGA devices are required in a single system. In this case, many thick and wide conductors may be needed for power connections while many minimum width conductors may be desirable for routing high speed input and output signals. Thus a larger substrate is often needed for the increased routing requirements while the area needed for routing all of these signals should be minimized for the highest possible system performance.

Rather than using a PCB as the substrate upon which the FPGAs are mounted, a large portion of a silicon wafer can be used as the substrate. Even with the use of such a silicon substrate, multiple layers with multiple cross-overs are used to route the large number of signals and power. The addition of multiple layers to allow for the requisite signal density further decreases performance and increases fabrication costs.

U.S. Pat. No. 6,221,769 discusses a method to decrease the density of signal lines and increase performance by creating a semiconductor chip package having a silicon substrate with substrate vias for connecting to a power source and other electronic devices. A plurality of integrated circuit dice is connected to multilevel wiring layer using die bonding bumps. Power is routed from integrated circuit die through die bonding bumps through the multilevel wiring layer and to the bonding balls through substrate vias.

U.S. Pat. No. 6,379,982 discusses a semiconductor wafer-on-wafer package which is shown in FIG. 1 (Prior Art). FIG. 1 displays a cross-sectional drawing of a portion of an unsingulated die of a wafer-on-wafer package, the wafer-on-wafer package constructed for the purpose of testing and burning-in the die prior to singulation. In FIG. 1, die bond pad 202 is shown protruding slightly downward from the bottom surface of device wafer 200 that is the active surface of a semiconductor die contained therein. Conductive trace 215, which may be copper, a copper based alloy, or any suitable electrically conductive material is disposed on support wafer 225 and is shown extending to bond pad connection point 204. The bond pad connection point is a solder ball or bump and is disposed upon conductive trace 215. Through-wafer via 210 is preformed in support wafer 225 prior to attaching device wafer 200 to support wafer 225. The through-wafer via is created by laser drilling, electrochemical anodization, or by an etching process and has an internal diameter of approximately sixty microns. Conductive filling material 206 is disposed within through-wafer via 210 such that an electrical connection is made to device wafer 200 through die bond 202, by bond pad connection point 204, conductive filling material 206, and bump 207. Bump 207 is electrically conductive and is used to make electrical contact to mounting pad 208 of mounting substrate 209. Gap 201 is shown between the device wafer 200 and passivation layer 205.

While the prior art drawing of FIG. 1 illustrates a method of producing a silicon package with through-wafer vias, the silicon assemblies described generally do not provide connections to multiple semiconductor integrated circuits disposed on device wafer 200. Thus the wafer-on-wafer assembly does not appear to have multiple conductive layers of varying thicknesses necessary both to provide power and to route thousands of connections from one semiconductor IC to another. A different method of making a semiconductor assembly is therefore desired that supports: 1) construction of thin, fine-pitch conductors for routing signal connections between a plurality of semiconductor ICs, 2) construction of thick conductors, characterized as having large feature sizes, for the lateral conduction of power to the semiconductor ICs, 3) through-holes for connecting the power supply through a semiconductor body to facilitate the increased density of thin conductors between semiconductor ICs on the silicon substrate, and 4) bypass capacitance closely adjacent the power conductors recognizing the limited space available on the silicon substrate.

### SUMMARY

A plurality of FPGA dice or other components is disposed upon a novel substrate structure. In order to 1) connect thousands of interconnect lines between the FPGA die, and 2) supply the immense amount of power required for these types of devices, the novel substrate structure includes a semiconductor substrate including an amount of single-crystal semiconductor material. The novel substrate structure includes many conductive vias as well as thick conductor layers. The vias are approximately twenty-five microns or greater in diameter, and are at least two hundred fifty microns long. These vias are used to electrically couple thick conductors on the bottom surface of the semiconductor substrate to other thick conductors on the other side of the semiconductor substrate (disposed in multiple layers below the plurality of FPGA dice). The thickness of the semiconductor substrate is at least two hundred fifty microns and is preferably approximately five hundred microns.

Each via includes a first metal tube, and a second metal tube of a smaller diameter disposed inside of and coaxially with respect to the first metal tube. A thin layer of dielectric separates the first and second coaxial metal tubes such that the tubes and dielectric layer form a cylindrical capacitor structure. In one example, each via has a capacitance of approximately one to two picofarads. The dielectric material can be a high-K dielectric. The many capacitive vias are disposed uniformly across the semiconductor substrate at a high density similar to the high density of power bumps present on FPGA dice mounted in flip-chip fashion to the semiconductor substrate. In one example, the via density is approximately 60,000 vias per square inch of semiconductor substrate. The novel capacitive vias provide approximately 0.1 microfarads of bypass capacitance per square centimeter of substrate area (about 0.6 microfarads per square inch), and additional bypass capacitance is provided due to parallel plate capacitance in metallization layers at the upper surface of the substrate structure. In an example in which the semiconductor substrate is at least one inch wide, and at least two inches long, the many vias provide a combined bypass capacitance of at least 1.2 microfarads.

The capacitive vias provide many power and ground connections that extend vertically through the semiconductor substrate and down into laterally extending thick strip-like conductors. The laterally extending thick strip-like conductors disposed on the underside of the semiconductor substrate are two microns or more in thickness. Power and ground current paths traverse a minimal lateral distance on the underside of the substrate structure before extending vertically through vias to the upper surface of the semiconductor substrate and to FPGA die-bonding bumps disposed upon the upper surface of the substrate structure. These die-bonding bumps are arrayed to match the corresponding array of lands present on the face side of the particular FPGAs to be attached to the substrate structure. Alternatively, the FPGA die may be have die-bonding bumps that match up with lands on the upper surface of the substrate structure.

On the underside of the novel substrate structure, coupled to the thick strip-like conductors, is a set of bus bar structures that corresponds to the set of strip-like thick conductors. Some bus bars are used to supply a supply voltage and are referred to as “power bus bars”. Other bus bars are used to provide grounding and are referred to as “ground bus bars”. These bus bars are made of solid copper or a similar conductive material and are approximately 1.5 millimeters high by 1.5 millimeters wide. There are ten or so of these bus bars and each bus bar spans the entire width of the semiconductor substrate. Each copper bus bar is coupled by a hundred or more local vertically-extending vias up to the footprint area of each FPGA on the upper surface of the substrate structure such that the IR drop between the bus bar and the FPGA is less than approximately twenty to thirty millivolts. This small amount of voltage loss can be compensated for by a similar increase in the supply voltage supplied between the power bus bars and the ground bus bars.

During operation of the semiconductor device (operation of the FPGAs on top of the substrate structure), expansion and contraction caused by rapid heating to a high temperature and subsequent cooling may stress the power connection structure at the junctions of different materials. The vertical vias also serve to reduce stress at the junctions of the copper plane and semiconductor material by riveting the copper plane to the semiconductor substrate at thousands of locations.

In one example, the novel substrate structure having the many capacitive vias is formed by the following method. A first oxide layer (for example, thermal oxide) is formed on the second surface of a planar semiconductor substrate. At least two parallel spaced apart through-holes are formed in the substrate, each through-hole extending from the first planar surface of the substrate, through the substrate, and to the second planar surface of the substrate. A first layer of conductive material is deposited on the surfaces inside the through-holes and on the first planar surface of the semiconductor substrate. A first layer of dielectric (for example, high-K dielectric) is deposited on the surfaces inside the through-holes and on the first planar surface of the semiconductor substrate. A second layer of conductive material is deposited on the surfaces inside the through-holes and on the first planar surface of the semiconductor substrate. A first opening is formed through the second relatively thick layer of electroplated copper. The through-holes are filled with a dielectric having a coefficient of thermal expansion that matches the coefficient of thermal expansion of the semiconductor substrate (dcte) as closely as possible. A second layer is also deposited on the first planar surface and the exposed surfaces of the first opening.

A second opening is formed through the dcte. A third opening is formed through the dcte in the first opening to the first layer of conductive material. A third layer of conductive material is deposited on the surfaces inside the second and third openings and on the first planar surface of the semiconductor substrate. Portions of the third layer of conductive material are removed leaving disconnected portions of conductive material over the first opening and the second opening. A fourth opening to the first through-hole is formed through the first thermal oxide on a second surface of the planar semiconductor substrate. A portion of the second layer of conductive material is removed from the end of the through-hole in the fourth opening.

A second oxide layer is deposited in the exposed surfaces in the fourth opening and on the first oxide layer on the second surface of the planar semiconductor substrate. A fifth opening in the second oxide layer is formed in the fourth opening to the second layer of electroplated copper. A sixth opening is formed in the first and second oxide layers to the first layer of conductive material in the end of the second through-hole. A fourth layer of conductive material is deposited on the surfaces inside the fifth and sixth openings and on the second planar surface of the semiconductor substrate. Portions of the fourth layer of conductive material are removed to leave disconnected first power and second power portions of conductive material over the fifth opening and the sixth opening.

Further details, embodiments and techniques are described in the detailed description below. This summary does not purport to define the invention. The invention is defined by the claims.

### BRIEF DESCRIPTION OF THE DRAWINGS

The accompanying drawings, where like numerals indicate like components, illustrate embodiments of the invention.

FIG. 1 (Prior Art) is a cross-sectional view of an unsingulated die mounted upon a semiconductor substrate with a single through-wafer via extending through a semiconductor support wafer.

FIG. 2 is a perspective view of a novel semiconductor device 250. Device 250 includes a novel substrate structure 251 and a plurality of FPGA dice mounted on top of substrate structure 251.

FIG. 3 is a partial enlarged view of the underside of substrate structure 251 of FIG. 2 showing the conducting vias and showing bus bars (only a couple of which are shown) extending under the substrate structure.

FIGS. 4 through 21 are schematic cross-sectional diagrams of steps of a method of forming a plurality of through-substrate power-conducting vias with embedded capacitance. FIG. 21 is a cross-sectional diagram of the resulting novel substrate structure.

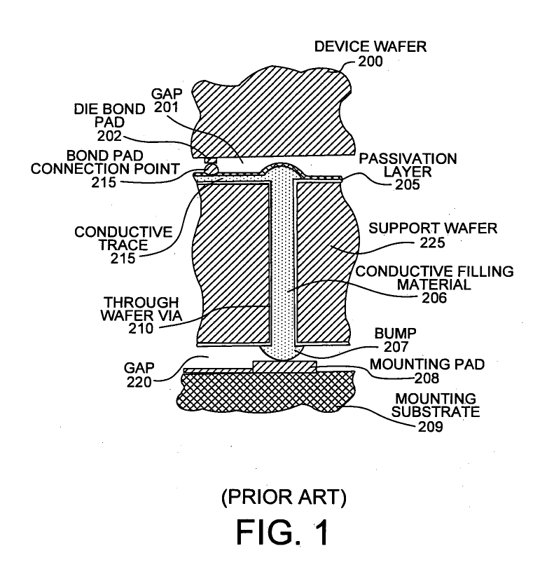

### DETAILED DESCRIPTION

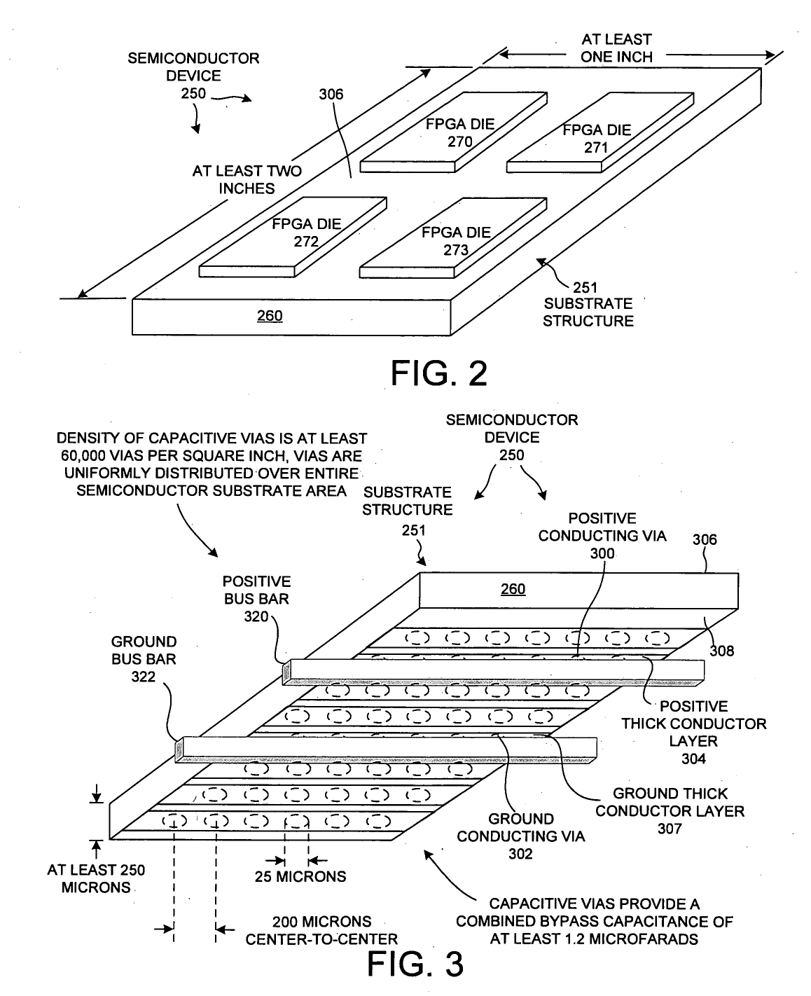

FIG. 2 is drawing of a fusion-bonded semiconductor device 250 in accordance with one novel aspect. A plurality of FPGA dice 270-273 is disposed upon a fusion-bonded substrate structure 251. In order to 1) connect thousands of interconnect lines between the FPGA die, and 2) supply the immense amount of power required for these types of devices, a semiconductor substrate is used for the substrate upon which the FPGA dice are mounted.

As shown in FIG. 3, the substrate structure 251 includes conductive through-holes or vias 300 and 302 and thick conductor layers 304 and 307. The through-holes 300 and 302, approximately twenty-five microns or greater in diameter, are used to electrically couple the thick conductors 304 and 307 on the bottom plane or surface 308 of the semiconductor substrate 260 to corresponding thick conductors 312 and 316 (see FIG. 21) present on the upper surface 306 of the semiconductor substrate 260 below the plurality of FPGA dice. The vias 300 and 302 in this power connection structure involve a dielectric between layers of electroplated copper, as further explained below, and are of a high density similar to the high density of power bumps (not shown) present on FPGA dice mounted to the semiconductor substrate. The density of vias illustrated in FIG. 3 is much lower than the density is in the real substrate structure. Vias 300 and 302 provide power and ground connections that extend vertically down through the semiconductor substrate into the laterally extending strip-like thick conductors 304 and 307 on the bottom surface of the semiconductor substrate. In the preferred embodiment, the thickness of the semiconductor substrate is at least two hundred fifty microns and is preferably approximately five hundred microns. Other thicknesses can, however, be used.

The strip-like laterally-extending thick conductors 304 and 307 are approximately two microns or more in thickness. Power and ground current paths traverse a minimal lateral distance on bottom surface 308 before they extend vertically up through the semiconductor substrate and to the upper surface of the semiconductor substrate to FPGA die-bonding bumps (not shown) disposed upon the surface of the semiconductor substrate. These die bonding bumps are arrayed to match the corresponding array of lands (not shown) present on the particular FPGAs to be attached to the semiconductor substrate.

Contacting the thick strip-like conductors 304 and 307 on the underside of the semiconductor substrate is a plurality of bus bar structures 320 and 322 (only two bus bars are shown in the illustration of FIG. 3). In the preferred embodiment, the bus bars alternate between power and ground. Rows of vias are disposed above each bus bar. The bus bars are made of copper or a similar electroplated copper and are approximately 1.5 millimeters high by 1.5 millimeters wide. There are ten or so of these bus bars under the substrate structure and each bus bar spans the entire width of the semiconductor substrate as illustrated. Each bus bar may facilitate a hundred or more local vertical connections through vertically extending vias such that the IR drop between the bus bars on the underside of the semiconductor substrate and the integrated circuits above the semiconductor substrate is less than approximately twenty to thirty millivolts. This small amount of voltage loss can be compensated for by a similar increase in the supply voltage supplied between the power and ground bus bars. During circuit operation, expansion and contraction caused by rapid heating to a high temperature and subsequent cooling stresses the power connection structure at the junctions of different materials. Vias 300 and 302 also serve to reduce stress at the junctions of the copper planes and semiconductor material by riveting the copper planes to the semiconductor substrate at thousands of locations. The FPGAs, their connections, the substrate, the conductive layers and the bus bars of this device are similar to those disclosed in commonly owned U.S. patent application Ser. No. 11/975,966, filed Oct. 22, 2007, the subject matter of which is incorporated herein by reference.

In order to reduce the space needed on the substrate for bypass capacitors and to reduce parasitic inductance, a substrate structure (see FIG. 21) comprises the semiconductor substrate 260 and the plurality of vias 300 and 302. The vias extend from first surface 306 of the semiconductor substrate to second surface 308 of the semiconductor substrate. Each via 300 and 302 includes a first power conducting layer 330 (for example, an outer tube of metal), a dielectric layer 334 (for example, a high-K dielectric layer), and a second power conducting layer 338 (for example, an inner tube of metal). As shown in FIG. 3 and as explained above, the first bus bar 320 is coupled, through the thick strip-like conductor layer 304, to a first subset of power conducting vias. Via 300 is one of these vias. The second bus bar 322 is coupled, through the thick strip-like conductor layer 307, to a second subset of ground conducting vias. Via 302 is one of these vias.

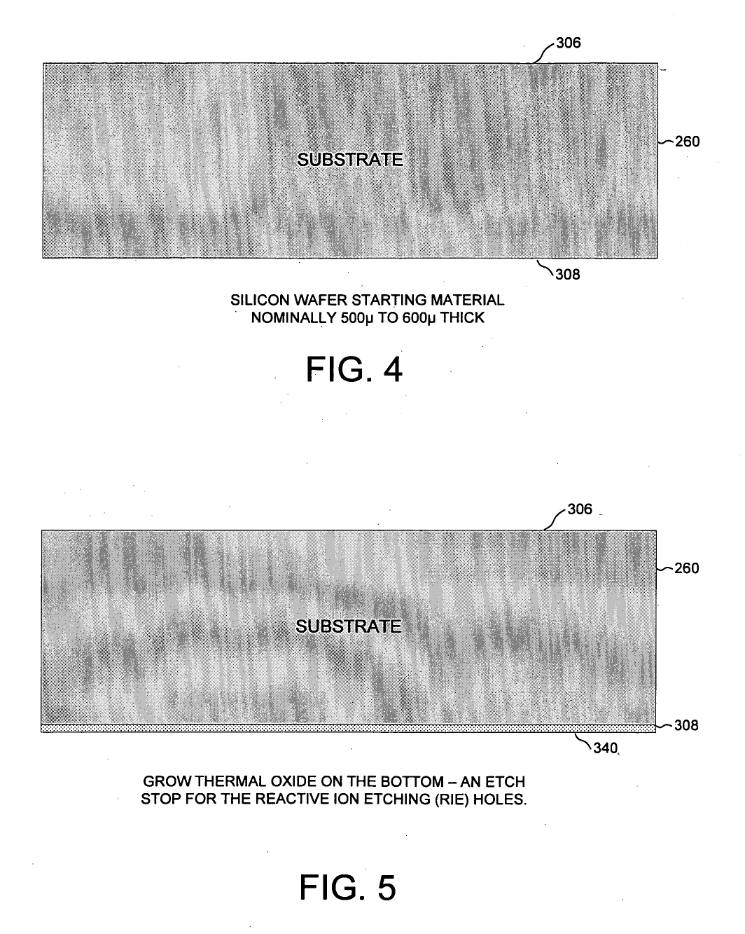

In one example, the substrate structure 251 of device 250 is formed by the following method. As shown in FIG. 4, the method begins with the planar semiconductor substrate 260 having the first planar major surface 306 and the parallel second planar major surface 308. Semiconductor substrate 260 is, in this particular example, a single-crystal semiconductor wafer about 500 to 600 microns thick.

As shown in FIG. 5, a first oxide layer 340 is formed on the second surface 308 of the planar semiconductor substrate. This first oxide layer 340 may, for example, be a thermal oxide layer.

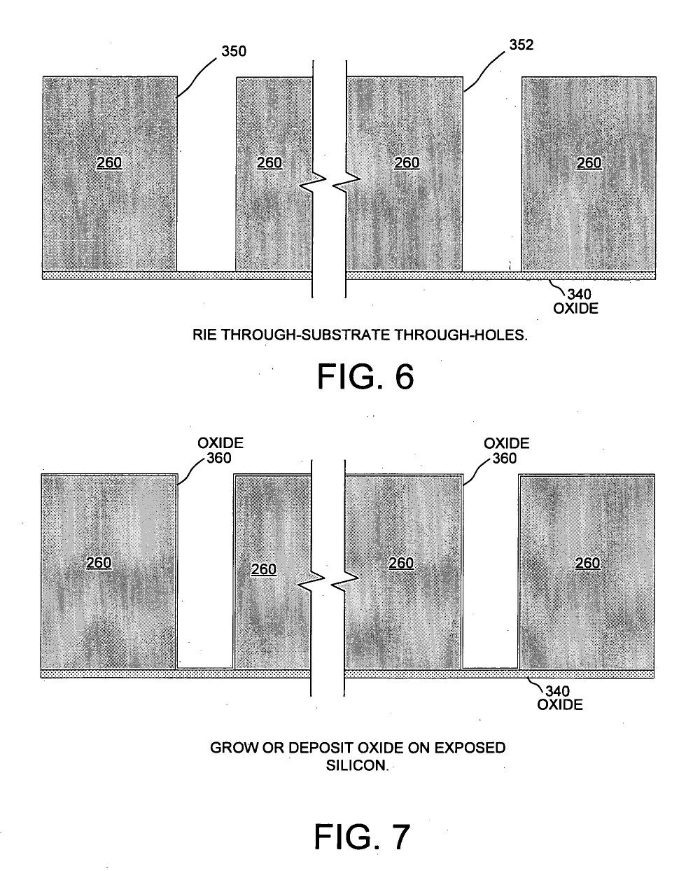

As shown in FIG. 6, parallel spaced apart through-holes 350 and 352 are formed by reactive ion etching in the substrate 260, each via extending from the first planar surface to the second planar surface. The illustrated break in the material in the illustration of FIG. 6 signifies how the actual spacing between through-holes is much greater than as shown. Although only two through-holes are illustrated, in the actual structure through-holes are uniformly distributed across the substrate with a center-to-center spacing of about two hundred microns.

As shown in FIG. 7, if an ordinary single-crystal silicon wafer is used, then thermal silicon oxide 360 is grown on the surfaces inside the through-holes and on the first planar surface 306 of the semiconductor substrate. If a high-K dielectric is used, this step can be omitted.

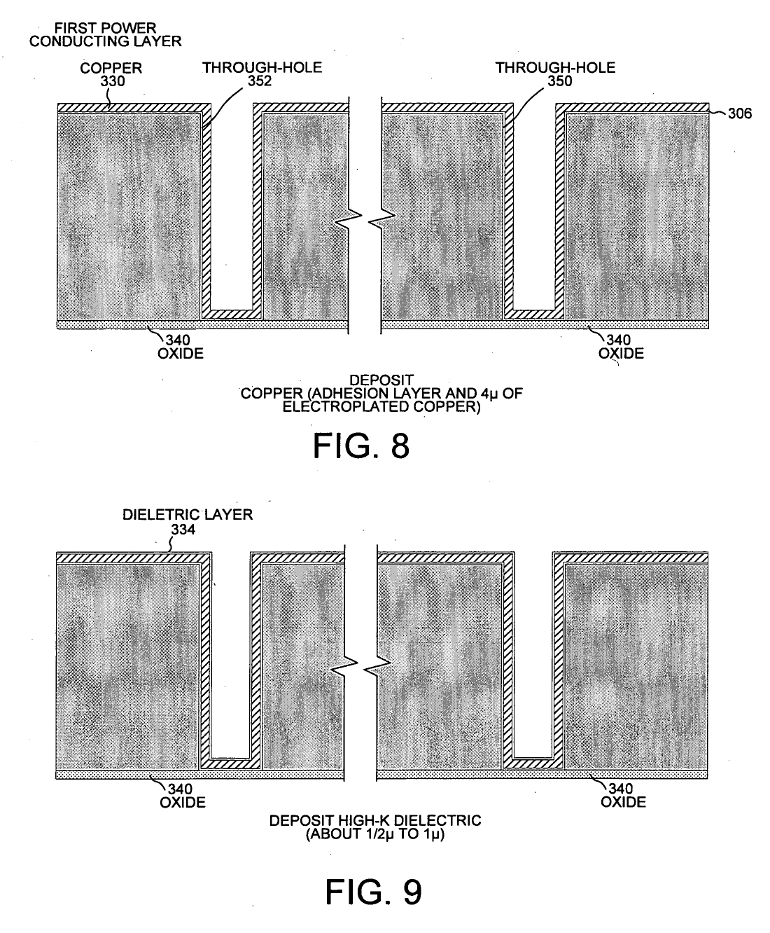

As shown in FIG. 8, an adhesive layer (not visible in the Figures) is deposited on the surfaces inside the through-holes and on the first planar surface 306 of the semiconductor substrate. A first relatively thick layer 330 (about 4 microns) of electroplated copper is then deposited on the surfaces inside the through-holes 350 and 352 and on the first planar surface 306 of the semiconductor substrate.

As shown in FIG. 9, a first relatively thin layer 334 (about one half micron to one micron) of dielectric is deposited on the surfaces inside the through-holes and across the upper surface of the substrate structure. The dielectric of layer 334 may, for example, be a high-K dielectric material.

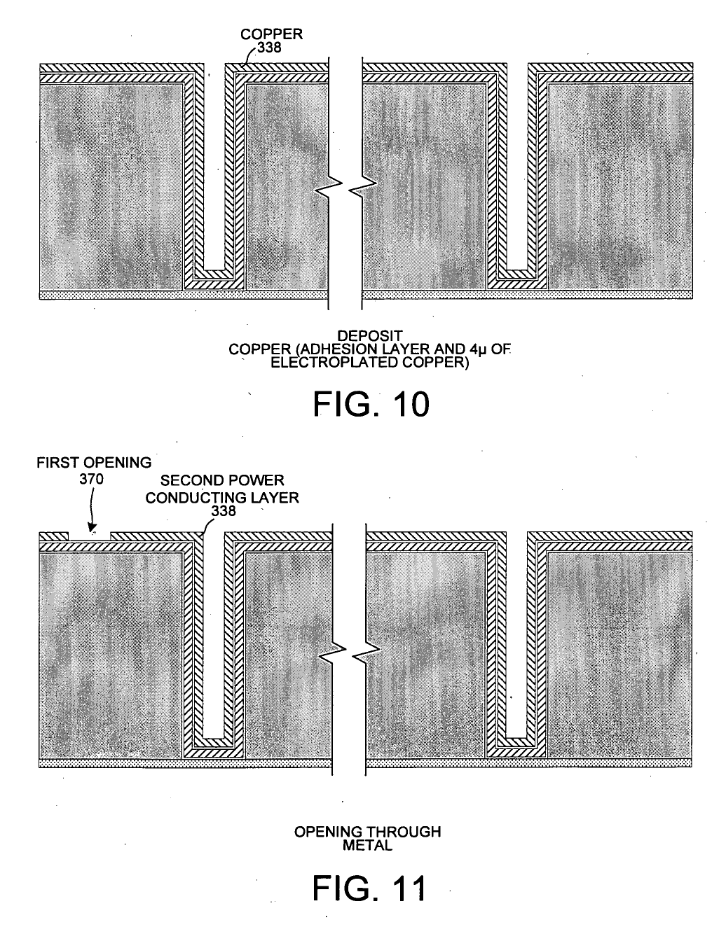

As shown in FIG. 10, a second relatively thick layer 338 (about 4 microns thick) of electroplated copper is deposited on the surfaces inside the through-holes and across the upper surface of the substrate structure as illustrated.

As shown in FIG. 11, a first opening 370 is formed through the second relatively thick layer 338 of electroplated copper.

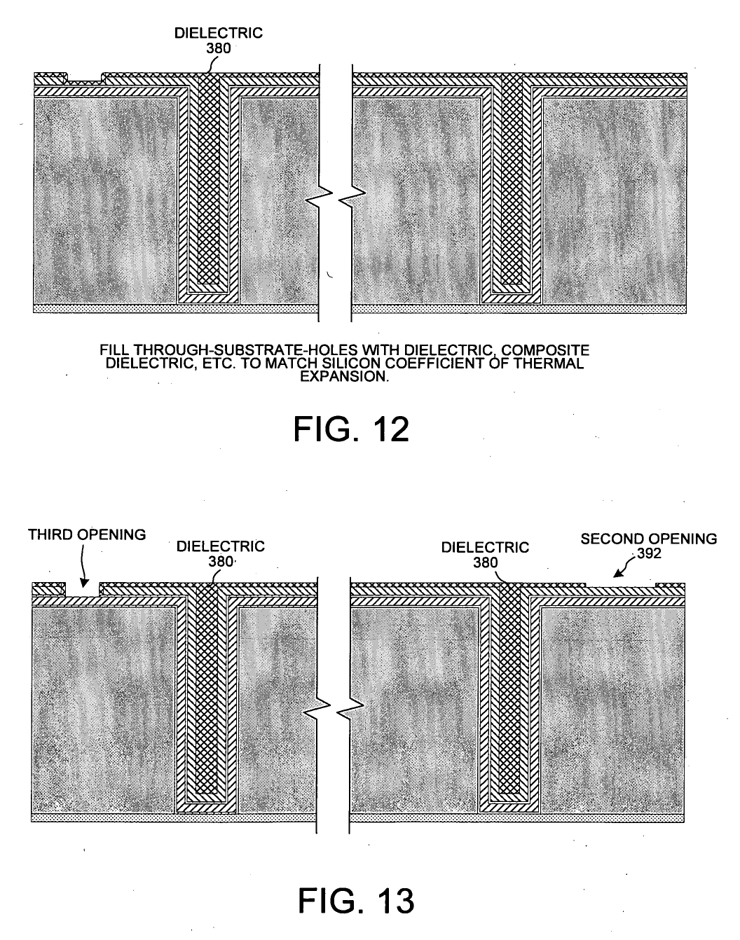

As shown in FIG. 12, the through-holes are filled with dielectric and a second relatively thin layer 380 of dielectric (about one half to one micron) is deposited across the upper surface of the substrate structure and into exposed portions of the first opening 370. Layer 380 has a dielectric that substantially matches the dielectric of the semiconductor substrate, and layer 380 also has a coefficient of thermal expansion that matches the coefficient of thermal expansion of the semiconductor substrate as closely as possible (dcte).

As shown in FIG. 13, a second opening 392 is formed through the dcte on the first planar surface of the substrate. A third opening is formed through the dcte in the first opening 370 to the first layer of electroplated copper.

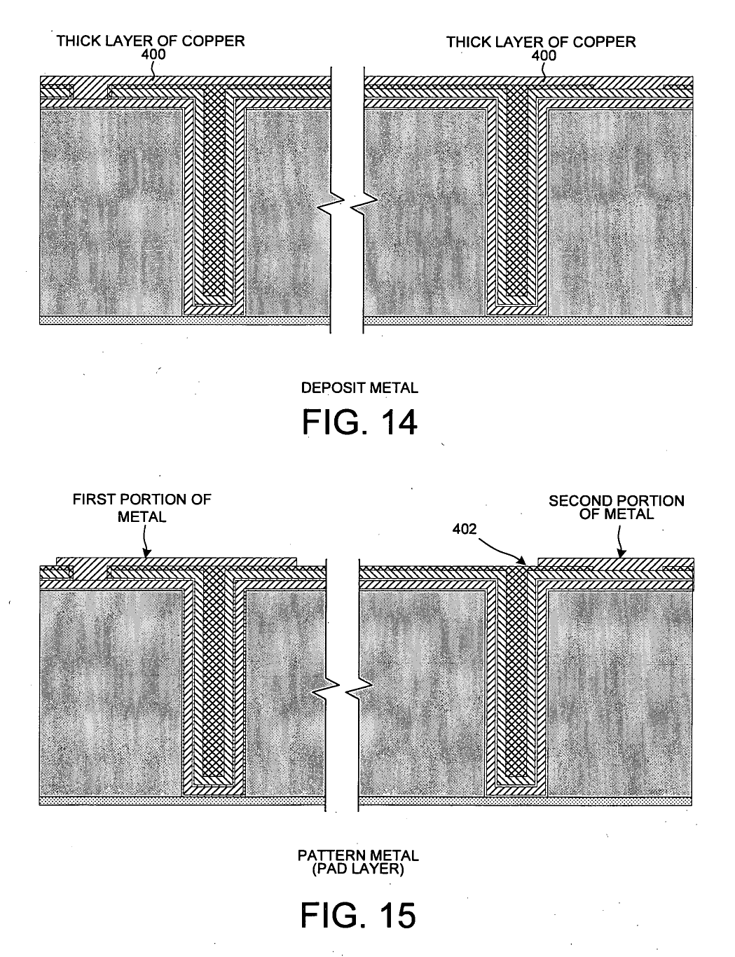

As shown in FIG. 14, a third relatively thick layer 400 of electroplated copper (about four microns) is deposited on the surfaces inside the second and third openings and across the upper surface of the substrate structure.

As shown in FIG. 15, portions of the third layer 400 of electroplated copper are removed 402 leaving disconnected portions of electroplated copper over the first/third opening and the second opening.

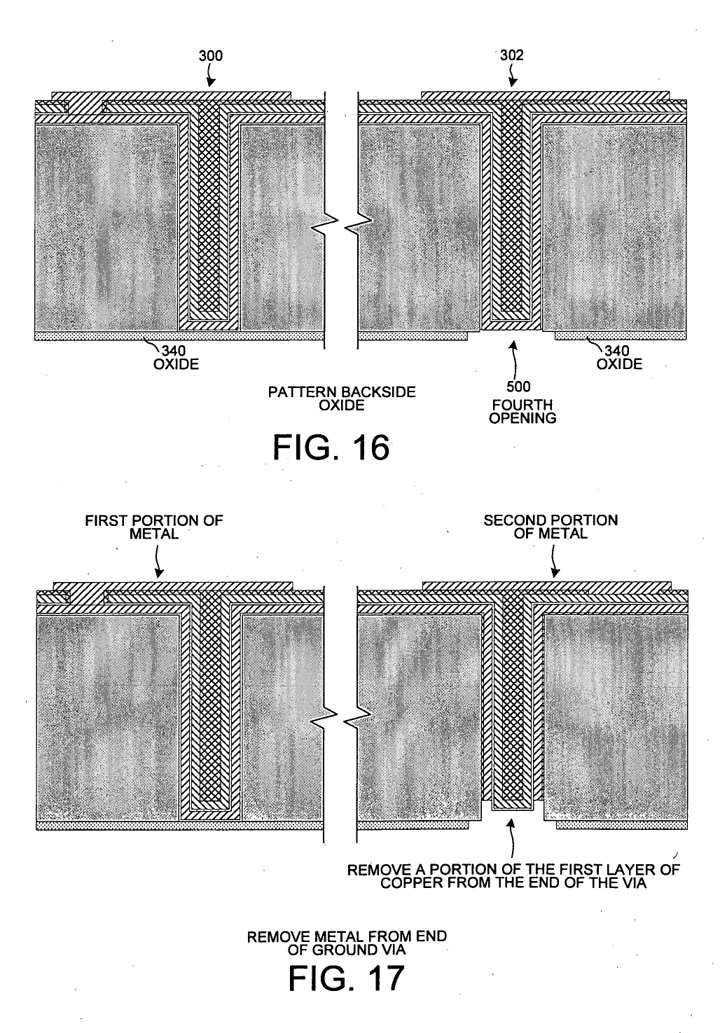

As shown in FIG. 16, a fourth opening 500 to the via 302 is formed through the first thermal oxide 340 on second surface 308 of the semiconductor substrate structure.

As shown in FIG. 17, a portion of the first layer of electroplated copper is removed from the bottom end of the via 302 in the fourth opening.

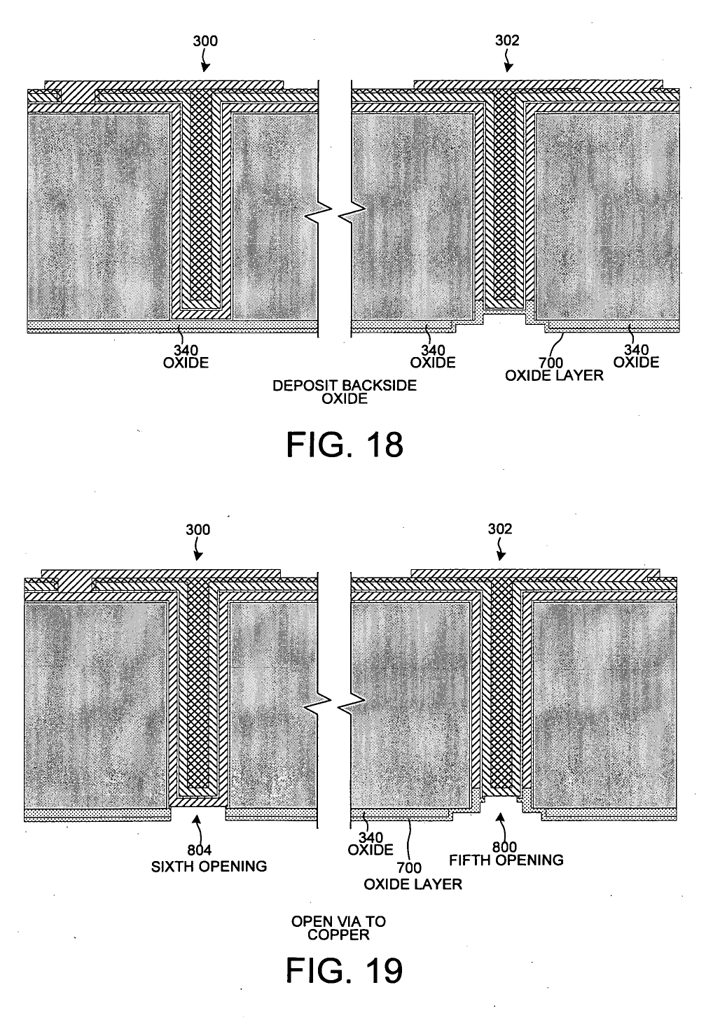

As shown in FIG. 18, a second oxide layer 700 is formed in the exposed surfaces in the fourth opening and on the first oxide layer 340 across the bottom surface 308 of semiconductor substrate structure.

As shown in FIG. 19, a fifth opening 800 in the second oxide layer 700 is formed in the fourth opening to the second layer of electroplated copper. A sixth opening 804 is formed in the first and second oxide layers 340 and 700 to the first layer of electroplated copper in the end of the second via 352. Although the openings 800 and 804 formed in FIG. 19 are so wide that the largely match up with the bottom metal portions of the vias, this is just a simplification for illustration purposes. In actuality, due to requirements of registration of the photolithographic process, the actual openings in the oxide would be smaller than is pictured.

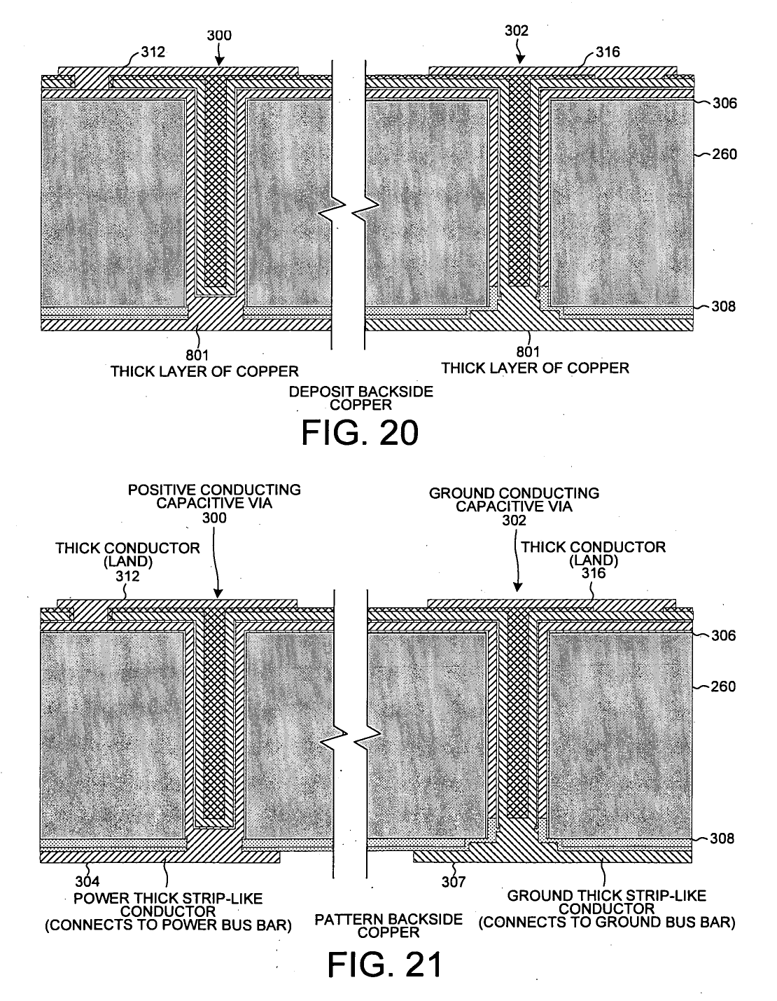

As shown in FIG. 20, a fourth relatively thick layer (about 4 micron) of electroplated copper is deposited on the surfaces inside the fifth and sixth openings and across the bottom surface 308 of the semiconductor substrate structure.

And as shown in FIG. 21, portions of the fourth layer of electroplated copper are removed to leave a thick strip-like conductor 304 for power and a thick strip-like conductor 307 for ground. Conductor 304 extends over opening 804 and makes contact with the bottom of via 300. Conductor 307 extends over opening 800 and makes contact with the bottom of via 302. On the top of the substrate structure, the conductor 312 is a land onto which a die-bonding bump (not shown) is fabricated. An electrical connection is established from the die-bonding bump, through the land, down through the through-substrate conductive via (illustrated on the left in FIG. 21), through first power portion 304, and to the bus bar 320, shown in FIG. 3. Each through-substrate conductive via serves as a high current power or ground connection to the FPGA die, as well as a bypass capacitor. In one example, the capacitance of a single through-substrate conductive via is approximately one picofarad. In one example, the novel substrate structure 251 has width of at least one inch, a length of at least two inches, and the vias provide a combined bypass capacitance of at least 1.2 microfarads.

Although certain specific embodiments are described above for instructional purposes, the teachings of this patent document have general applicability and are not limited to the specific embodiments described above. Although an example is described above where bare FPGA integrated circuit dice are surface mounted to a substrate structure, in other embodiments packaged FPGA integrated circuits are attached to the substrate structure. Although a capacitive via is described above that conducts substantial current through only one of its two coaxial metal tubes, other vias may conduct current one way through one of metal tubes and may conduct current the other way through the other metal tube of the via. Accordingly, various modifications, adaptations, and combinations of various features of the described embodiments can be practiced without departing from the scope of the invention as set forth in the claims.

1. An assembly comprising:
a semiconductor substrate including an amount of single-crystal semiconductor material, the semiconductor substrate having a first substantially planar major surface and a second substantially planar major surface;
a plurality of capacitive vias extending a distance of at least two hundred and fifty microns from the first substantially planar major surface of the semiconductor substrate to the second substantially planar major surface of the semiconductor substrate, each via including a first metal tube, a dielectric layer, and a second metal tube, wherein one of said tubes is disposed inside the other tube, the two tubes being separated by the dielectric layer, wherein each capacitive via has a capacitance of at least one picofarad;
a first bus bar being electrically coupled to a first subset of said plurality of vias adjacent the second substantially planar major surface of the semiconductor substrate; and
a second bus bar being electrically coupled to a second subset of said plurality of vias adjacent the second substantially planar major surface of the semiconductor substrate, wherein the first and second bus bars extend parallel to one another along the second substantially planar major surface of the semiconductor substrate.

2. The assembly of claim 1, wherein a current flows through the metal of one of the metal tubes from one of the first and second substantially planar major surfaces to the other of the first and second substantially planar major surfaces, and wherein substantially no current flows through the metal of the other of the metal tubes.

3. The assembly of claim 2, further comprising:
a first strip of metal that extends along the second substantially planar major surface of the semiconductor substrate, the first strip connecting the first subset of vias together at the second substantially planar major surface, wherein the first strip contacts the first bus bar; and
a second strip of metal that extends along the second substantially planar major surface of the semiconductor substrate, the second strip connecting the second subset of vias together at the second substantially planar major surface, wherein the second strip contacts the second bus bar.

4. The assembly of claim 1, wherein the semiconductor substrate has a length of at least two inches and a width of at least one inch, and wherein there are at least one hundred and twenty thousand capacitive vias in the semiconductor substrate.

5-8. (canceled)

9. An apparatus, comprising:
a semiconductor substrate that is at least two hundred and fifty microns thick, at least one inch wide, and at least two inches long, the semiconductor substrate having a first substantially planar major surface in a first plane, and having a second substantially planar major surface in a second plane, wherein the semiconductor substrate includes an amount of single-crystal semiconductor material; and
means for conducting a voltage supply current from a first power conductor disposed on a second side of the semiconductor substrate, through the substrate from the second surface to the first surface, and to a second power conductor disposed on a first side of the semiconductor substrate opposite the second side, and for conducting a ground current from a second ground conductor disposed on the first side of the semiconductor substrate, through the semiconductor substrate, and to a first ground conductor disposed on the second side of the semiconductor substrate, wherein the means provides a capacitance between the first power conductor and the first ground conductor of at least 1.2 microfarads, wherein the means is disposed substantially entirely between the first plane and the second plane.

10. The apparatus of claim 9, wherein the means includes a plurality of capacitive vias, each capacitive via including a first metal tube, a dielectric layer, and a second metal tube, wherein one of said metal tubes is disposed inside the other metal tube, the two metal tubes being separated by the dielectric layer, each capacitive via having a capacitance of at least one picofarad.

11. The apparatus of claim 10, wherein the first power conductor is a strip of metal that extends in a direction for at least one inch, and wherein the first ground conductor is a strip of metal that extends in a direction for at least one inch, wherein the first power conductor is at least two microns thick, and wherein the first ground conductor is at least two microns thick.

12-21. (canceled)

22. The assembly of claim 1, wherein a via of the plurality of capacitive vias is approximately twenty five microns in diameter.

23. The assembly of claim 1, wherein a first of the plurality of capacitive vias is disposed in the semiconductor substrate less than two hundred microns from a second of the plurality of capacitive vias.

24. The assembly of claim 1, wherein the dielectric layer is comprised of a high-K dielectric material with a coefficient of thermal expansion that closely approximates the coefficient of thermal expansion of the semiconductor substrate.

25. The assembly of claim 1, wherein the first bus bar has a height, a width, and a length, wherein the height is greater than 1.5 millimeters and the width is greater than 1.5 millimeters.

26. An apparatus comprising:
a plurality of capacitive vias extending a distance of at least two hundred and fifty microns from a first substantially planar major surface of a semiconductor substrate to a second substantially planar major surface of the semiconductor substrate, each via including a first metal tube, a dielectric layer, and a second metal tube, wherein one of said tubes is disposed inside the other tube, the two tubes being separated by the dielectric layer, wherein each capacitive via has a capacitance of at least one picofarad;
a first strip of metal that extends along the second substantially planar major surface of the semiconductor substrate, the first strip connecting a first subset of vias together at the second substantially planar major surface; and
a second strip of metal that extends along the second substantially planar major surface of the semiconductor substrate, the second strip connecting a second subset of vias together at the second substantially planar major surface.

27. The apparatus of claim 26, wherein the capacitive vias disposed in the semiconductor substrate are disposed at a density of sixty thousand capacitive vias per one square inch of area of the semiconductor substrate.

28. The apparatus of claim 26, wherein the capacitive vias disposed in the semiconductor substrate provide a capacitance value of 0.6 microfarads over an area of one square inch of the semiconductor substrate.

29. The assembly of claim 26, wherein a via of the plurality of capacitive vias is approximately twenty five microns in diameter.

30. The assembly of claim 26, wherein a first of the plurality of capacitive vias is disposed on the semiconductor substrate less than two hundred microns from a second of the plurality of capacitive vias.

31. The assembly of claim 26, wherein the dielectric layer is comprised of a high-K dielectric material with a coefficient of thermal expansion that closely approximates the coefficient of thermal expansion of the semiconductor substrate.

32. The apparatus of claim 26, wherein the semiconductor substrate includes an amount of single-crystal semiconductor material.

33. The apparatus of claim 26, wherein first strip of metal and the second strip of metal are at least two microns thick.

34. An apparatus comprising:
a first set of capacitive vias coupling a supply voltage from a power conductor on a second side of a semiconductor substrate, through the semiconductor substrate, and to an integrated circuit disposed on a first side of the semiconductor substrate, wherein the semiconductor substrate is at least two hundred and fifty microns thick and includes an amount of single-crystal semiconductor material; and
a second set of capacitive vias sinking current from the integrated circuit on the first side of the semiconductor substrate, through the semiconductor substrate, and to a ground conductor on the second side of the semiconductor substrate, wherein each via of the first and second sets involves a pair of coaxial tubes of metal, wherein one of the tubes is separated from the other by a layer of dielectric, and wherein each via has a capacitance of at least one picofarad.
